(19) United States
(12) Patent Application Publication
(10) Pub. No.: US 2008/0048282 A1
(43) Pub. Date: Feb. 28, 2008

(54) Semiconductor Device and Fabricating Method Thereof

(76) Inventor: JAE WON HAN, Soowon-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/831,560

(22) Filed: Jul. 31, 2007

(30) Foreign Application Priority Data
Aug. 23, 2006 (KR) 10-2006-0080117

(51) Int. Cl. H01L 31/0232; H01L 21/44; H01L 31/06; H01L 23/48

(52) U.S. Cl. 257/432; 257/461; 257/750; 257/762; 257/763; 257/764; 257/774; 438/65; 438/667; 257/E21.597; 257/E31.053; 257/E23.011

(57) ABSTRACT

A semiconductor device for a system in a package (SiP) type device can include a semiconductor substrate; a pre-metal-dielectric (PMD) layer on the semiconductor substrate; at least one metal layer on the PMD layer; a first through-electrode extending through the semiconductor substrate and the PMD layer; and a second through-electrode connected to the first through-electrode through the metal layer.

### CROSS-REFERENCE TO RELATED APPLICATION

The present application claims the benefit under 35 U.S.C. §119 of Korean Patent Application No. 10-2006-0080117, filed Aug. 23, 2006, which is hereby incorporated by reference in its entirety.

### BACKGROUND

An image sensor is used for a SiP (system in a package) type semiconductor device. The image sensor receives light to generate an electric signal.

The image sensor is typically aligned at an upper portion in the SiP type semiconductor device. In this case, a device must be provided to enable signal communication between the image sensor and elements positioned below the image sensor.

### BRIEF SUMMARY

An embodiment of the present invention provides a semiconductor device and a method of fabricating the same, which can easily provide signal communication between an image sensor aligned at an upper portion of a SiP type semiconductor device and elements positioned at lower portions of the SiP type semiconductor device.

A semiconductor device according to one embodiment comprises: a semiconductor substrate having a photodiode area and a transistor area; a pre-metal-dielectric (PMD) layer on the semiconductor substrate; at least one metal layer on the PMD layer; a first through-electrode extending through the semiconductor substrate and the PMD layer; and a second through-electrode connected to the first through-electrode and passing through the at least one metal layer.

A method of fabricating a semiconductor device according to an embodiment comprises the steps of: preparing a semiconductor substrate having a photodiode area and a transistor area; forming a PMD layer on the semiconductor substrate; forming a first through-electrode extending into the semiconductor substrate from a top surface of the PMD layer; forming at least one metal layer on the PMD layer; forming a second through-electrode connected to the first through-electrode and passing through the metal layer; and removing a bottom surface of the semiconductor substrate to expose the first through-electrode.

In a further embodiment, a semiconductor device can be provided, comprising: an image sensor including a semiconductor substrate having a photodiode area and a transistor area, a PMD layer on the semiconductor substrate, at least one metal layer on the PMD layer, a first through-electrode extending through the semiconductor substrate and the PMD layer and a second through-electrode connected to the first through-electrode and passing through the at least one metal layer; a second device provided below the image sensor; and a connection layer interposed between the image sensor and the second device to electrically connect the first through-electrode of the image sensor to a circuit electrode of the second device.

### BRIEF DESCRIPTION OF THE DRAWINGS

FIGS. 1 to 5 are views showing a method for manufacturing an image sensor according to an embodiment; and

FIG. 6 is a view showing a SiP type semiconductor device fabricated through a method of manufacturing a semiconductor device according to an embodiment.

### DETAILED DESCRIPTION

In the description of embodiments, it will be understood that when a layer (or film) is referred to as being ‘on/above/over/upper’ another layer or substrate, it can be directly on another layer or substrate, or intervening layers may also be present. Further, it will be understood that when a layer is referred to as being ‘down/below/under/lower’ another layer, it can be directly under another layer, and one or more intervening layers may also be present. In addition, it will also be understood that when a layer is referred to as being ‘between’ two layers, it can be the only layer between the two layers, or one or more intervening layers may also be present. Thus, the meaning thereof must be determined based on the scope of the present invention.

Hereinafter, a semiconductor device and fabricating method thereof according to embodiments of the present invention will be described with reference to accompanying drawings.

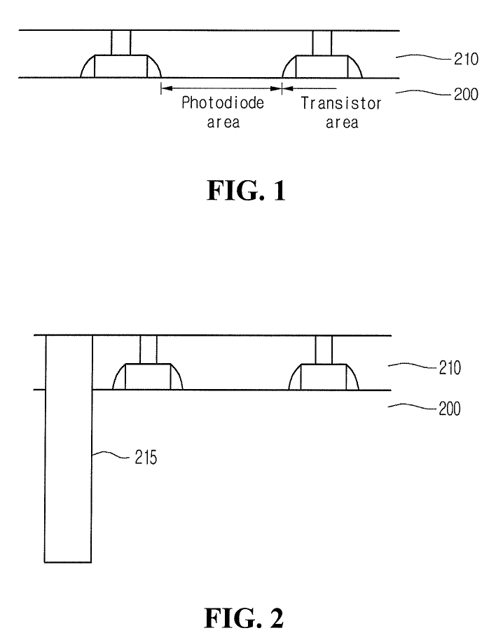

FIGS. 1 to 5 are views showing a method for manufacturing an image sensor according to an embodiment.

Referring to FIG. 1, a semiconductor substrate 200 formed with a photodiode area and a transistor area is prepared. Then, a PMD (Pre Metal Dielectric) layer 210 is formed on the semiconductor substrate 200.

The photodiode area and the transistor area can be formed on a top surface of the semiconductor substrate 200. In addition, a contact can be formed in the PMD layer 210. The method of fabricating the PMD layer 210 is generally known in the art, so detailed description thereof will be omitted.

Then, referring to FIG. 2, a first through-electrode 215 is formed such that the first through-electrode 215 extends from a top surface of the PMD layer 210 to a predetermined portion of the semiconductor substrate 200. The first through-electrode 215 extends below an isolation layer (not shown) formed in the semiconductor substrate 200.

The first through-electrode 215 can be obtained by sequentially performing patterning, etching and metal processes with respect to the PMD layer 210 and the semiconductor substrate 200. The first through-electrode 215 can be fabricated by using a material including at least one selected from the group consisting of tungsten (W), copper (Cu), aluminum (Al), silver (Ag) and gold (Au). The first through-electrode 215 can be formed by, for example, chemical vapor deposition (CVD), physical vapor deposition (PVD), evaporation, or electrochemical plating (ECP). In addition, a barrier metal can be formed in the first through-electrode 215. In certain embodiments, TaN, Ta, TiN, Ti or TiSiN can be used as a barrier metal for the first through-electrode 215. The barrier metal can be formed using, for example, CVD, PVD, or atomic layer deposition (ALD).

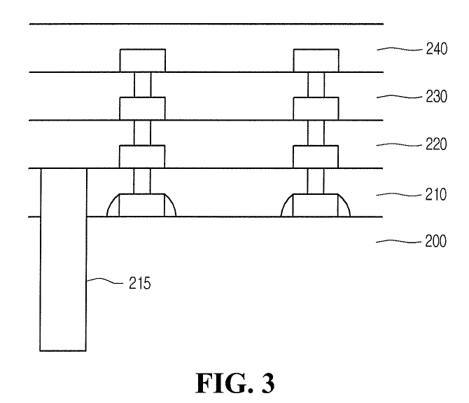

Referring to FIG. 3, at least one metal layer is formed on the PMD layer 210. Although FIG. 3 shows first to third metal layers 220, 230 and 240, the number of metal layers may vary depending on the interconnection design or applications thereof.

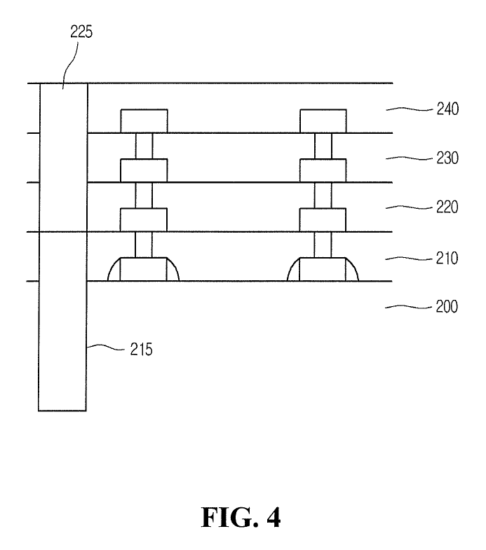

Then, after forming the metal layers, referring to FIG. 4, a second through-electrode 225 connected to the first through-electrode 215 can be formed.

In an embodiment, the second through-electrode 225 can be formed by sequentially performing patterning, etching and metal forming processes with respect to the third metal layer 240, the second metal layer 230 and the first metal layer 220. In one embodiment, a pattern for the second through-electrode can be formed, and that same pattern can be used as an etch mask for etching the third metal layer 240, the second metal layer 230 and the first metal layer 220. After the layers are etched to expose a top surface of the first through-electrode 215, a metal forming process can be performed to form the second through-electrode 225.

The second through-electrode 225 can be fabricated by using a material including at least one selected from the group consisting of W, Cu, Al, Ag and Au. The second through-electrode 225 can be formed using, for example, CVD, PVD, evaporation, or ECP. In addition, a barrier metal can be formed for the second through-electrode 225. In certain embodiments, TaN, Ta, TiN, Ti or TiSiN can be used as a barrier metal for the second through-electrode 225. The barrier metal can be formed, for example, through CVD, PVD, or ALD.

After the second through-electrode 225 has been formed, subsequent processes, such as processes of forming a color filter and a micro-lens on the third metal layer 240, can be performed to fabricate the image sensor. In such embodiments, the color filter selectively filters light incident into the photodiode area of the semiconductor substrate on the basis of the wavelengths of the light; and the micro-lens collects the incident light.

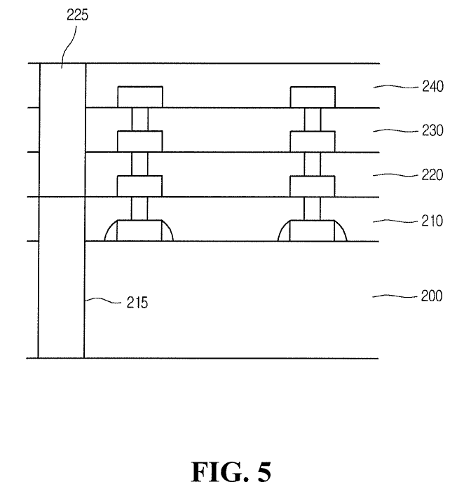

Referring to FIG. 5, a bottom surface of the semiconductor substrate 200 is removed to expose the first through-electrode 215. In one embodiment, the bottom surface of the semiconductor substrate 200 is polished to expose the first through-electrode 215.

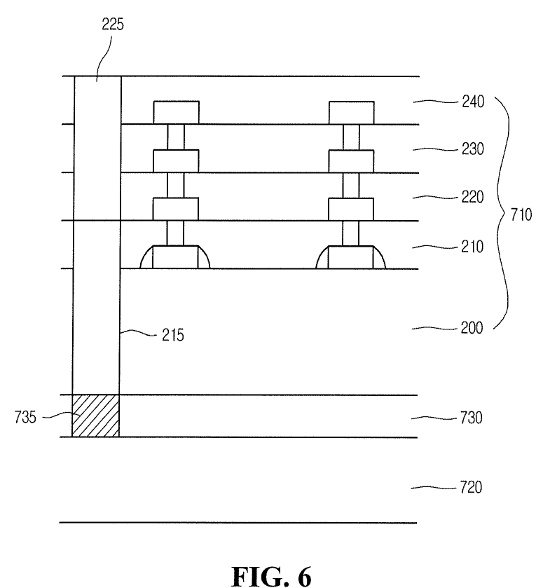

The image sensor fabricated as described above can be stacked on an SiP type semiconductor device as shown in FIG. 6.

Referring to FIG. 6, an SiP type semiconductor device can include an image sensor 710, a second device 720 and a connection layer 730 electrically connecting the image sensor 710 to the second device 720.

In an embodiment, the image sensor 710 includes the semiconductor substrate 200 formed with a photodiode area and a transistor area, the PMD layer 210 formed on the semiconductor substrate 200 and first to third metal layers 220, 230 and 240 formed on the PMD layer 210. In addition, the image sensor 710 includes the first through-electrode 215 extending through the semiconductor substrate 200 and the PMD layer 210 and the second through-electrode 225 extending through the first to third metal layers 220, 230 and 240 to connect with the first through-electrode 215.

The second device 720 is electrically connected to the image sensor 710 by means of the connection layer 730. The connection layer 730 can be provided with a connection electrode 735 that electrically connects the first through-electrode 215 of the image sensor 710 to a circuit electrode of the second device 720. The second device 720 can be, for example, a CPU, an SRAM, a DRAM, a flash memory, a logic LSI, a Power IC, a control IC, an analog LSI, an MM IC, a CMOS RF-IC, a sensor chip, or a MEMS chip.

According to an embodiment, signal communication can be easily achieved between the image sensor 710 and the second device 720 disposed below the image sensor 710 by means of the first and second through-electrodes 215 and 225 formed in the image sensor 710.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A semiconductor device comprising:
a semiconductor substrate;
a pre-metal-dielectric (PMD) layer on the semiconductor substrate;
at least one metal layer on the PMD layer;
a first through-electrode extending through the semiconductor substrate and the PMD layer; and
a second through-electrode connected to the first through-electrode through the metal layer.

2. The semiconductor device according to claim 1, wherein the first and second through-electrodes include at least one selected from the group consisting of W, Cu, Al, Ag and Au.

3. The semiconductor device according to claim 1, wherein the semiconductor substrate comprises a photodiode area and a transistor area, the semiconductor device further comprising:
a color filter formed on the metal layer to filter light incident onto the photodiode area.

4. The semiconductor device according to claim 1, wherein the semiconductor substrate comprises a photodiode area, a transistor area, and an isolation layer, and
wherein the first through-electrode extends below the isolation layer.

5. A method of fabricating a semiconductor device, the method comprising the steps of:
preparing a semiconductor substrate having a photodiode area and a transistor area;
forming a pre-metal-dielectric (PMD) layer on the semiconductor substrate;
forming a first through-electrode extending into the semiconductor substrate from a top surface of the PMD layer;
forming at least one metal layer on the PMD layer;
forming a second through-electrode connected to the first through-electrode through the metal layer; and
removing a bottom surface of the semiconductor substrate to expose the first through-electrode.

6. The method according to claim 5, further comprising, after forming the second through-electrode, forming a color filter on the metal layer to filter light incident into the photodiode area.

7. The method according to claim 5, wherein removing a bottom surface of the semiconductor substrate comprises polishing the bottom surface of the semiconductor substrate to expose the first through-electrode.

8. The method according to claim 5, wherein the first and second through-electrodes include at least one selected from the group consisting of W, Cu, Al, Ag and Au.

9. The method according to claim 5, wherein preparing the semiconductor substrate having the photodiode area and the transistor area comprises forming an isolation layer, and wherein the first through-electrode extends below the isolation layer.

10. A semiconductor device comprising:
an image sensor comprising:
a semiconductor substrate having a photodiode area and a transistor area,
a pre-metal-dielectric (PMD) layer on the semiconductor substrate,
at least one metal layer on the PMD layer,
a first through-electrode extending through the semiconductor substrate and the PMD layer, and
a second through-electrode connected to the first through-electrode through the metal layer;
a second device provided below the image sensor; and
a connection layer interposed between the image sensor and the second device to electrically connect the first through-electrode of the image sensor to a circuit electrode of the second device.

11. The semiconductor device according to claim 10, wherein the first and second through-electrodes of the image sensor include at least one selected from the group consisting of W, Cu, Al, Ag and Au.

12. The semiconductor device according to claim 10, wherein the image sensor further comprises a color filter formed on the metal layer to filter light incident onto the photodiode area.

13. The semiconductor device according to claim 10, wherein the image sensor further comprises an isolation layer on the semiconductor substrate having the photodiode area and the transistor area, wherein the first through-electrode extends below the isolation layer.
